(19) United States
(12) Patent Application Publication
(10) Pub. No.: US 2026/0334029 A1
(43) Pub. Date: Oct. 22, 2026

(54) DISPLAY DEVICE AND METHOD FOR MANUFACTURING THE SAME

(71) Applicant: XIAMEN TIANNA DISPLAY TECHNOLOGY CO., LTD., Xiamen (CN)

(72) Inventor: Sunkeun CHO, Xiamen (CN)

(21) Appl. No.: 19/691,495

(22) Filed: May 28, 2026

(30) Foreign Application Priority Data
Nov. 26, 2025 (CN) 202511755616.4

(51) Int. Cl. H10K 59/131; H05K 1/189; H10K 59/12; H10K 59/80

(52) U.S. Cl. CPC H10K 59/131; H05K 1/189; H10K 59/1201; H10K 59/873; H05K 2201/10128

(57) ABSTRACT

A display device includes a display panel, first conductive portions, second conductive portions, a driving assembly, and connecting portions. The driving assembly is located on a side of the backlight surface of the display panel. First conductive portions are provided on a side of the light-emitting surface of the display panel, and second conductive portions are provided on a side of the driving assembly away from the display panel. The connecting portions at least cover a surface of a side of one of first conductive portions away from one of second conductive portions, a surface of a side of the second conductive portion away from the first conductive portion, a side surface of the display panel, and a side surface of the driving assembly. The first conductive portion is electrically connected to the second conductive portion through the connecting portions.

### CROSS-REFERENCE TO RELATED APPLICATION

The present application claims priority to Chinese Patent Application No. 202511755616.4, filed on Nov. 26, 2025, the content of which is incorporated herein by reference in its entirety.

### TECHNICAL FIELD

The present disclosure relates to the field of display technologies, and in particular, to a display device and a method for manufacturing the display device.

### BACKGROUND

At present, with the rapid development of display technology, Organic Light-emitting Diode (OLED) display screens have been increasingly widely applied owing to their advantages such as a wide viewing angle, low power consumption, fast response speed, no need for a backlight, a wide color gamut, high contrast, and a thin and light overall structure. With the development of science and technology, the demand for a larger displayable region of display modules in electronic devices such as mobile phones and smart watches has been growing, and bezels of the display modules have become increasingly narrow. Various display module manufacturers are all committed to narrowing the bezels of display modules, and a narrow bezel has become one of the main competitiveness of products.

### SUMMARY

An aspect of the present disclosure provides a display device. The display panel includes a display panel, a plurality of first conductive portions, a plurality of second conductive portions, a driving assembly, and a plurality of connecting portions. The display panel includes a light-emitting surface and a backlight surface opposite to each other, and the driving assembly is located on a side of the backlight surface of the display panel. The plurality of first conductive portions is provided on a side of the light-emitting surface of the display panel, and the plurality of second conductive portions is provided on a side of the driving assembly away from the display panel. One of the plurality of connecting portions at least covers a surface of a side of one of the plurality of first conductive portions away from one of the plurality of second conductive portions, a surface of a side of one of the plurality of second conductive portions away from one of the plurality of first conductive portions, a side surface of the display panel, and a side surface of the driving assembly; and one of the plurality of first conductive portions is electrically connected to one of the plurality of second conductive portions through one of the plurality of connecting portions.

Another aspect of the present disclosure provides a method for manufacturing a display device, which is configured to manufacture the above display device. The method includes: providing the display panel, and manufacturing the first conductive portions on the side of the light-emitting surface of the display panel; manufacturing the support protective film on the side of the backlight surface of the display panel, in which the support protective film includes the first region beyond the side surface of the display panel; coating the first conductive adhesive on a side of the first conductive portion away from the support protective film, so that on the support protective film in the first region, the first conductive adhesive covers the side of the first conductive portion away from the support protective film and the side surface of the display panel; curing the first conductive adhesive; removing the support protective film; providing the driving assembly, and manufacturing the second conductive portions on a side of the driving assembly; fixing a side of the driving assembly away from the second conductive portion to the backlight surface of the display panel; coating the second conductive adhesive on a side of the second conductive portion away from the display panel and the side surface of the driving assembly, so that the second conductive adhesive covers the side of the second conductive portion away from the display panel and the side surface of the driving assembly; and curing the second conductive adhesive, in which the first conductive adhesive is electrically connected to the second conductive adhesive to form the plurality of connecting portions, and one of the plurality of first conductive portion is electrically connected to one of the plurality of second conductive portion through the plurality of connecting portions.

### BRIEF DESCRIPTION OF DRAWINGS

The drawings herein are incorporated in and constitute a part of the description, which illustrate embodiments in accordance with the present disclosure and, together with the description, serve to explain the principles of the present disclosure.

In order to more clearly illustrate the technical solutions in the embodiments of the present disclosure or in the related art, the drawings, which are intended to be used in the description of the embodiments or the related art, are briefly described as below, and it will be apparent that other drawings may be obtained by those skilled in the art according to these drawings.

FIG. 1 is a schematic planar structural diagram of a side of a light-emitting surface of a display panel of a display device according to some embodiments of the present disclosure;

FIG. 2 is a schematic planar structural diagram of a side of a backlight surface of the display panel of the display device shown in FIG. 1 according to some embodiments of the present disclosure;

FIG. 3 is a cross-sectional view along a direction A-A′ shown in FIG. 1 according to some embodiments of the present disclosure;

FIG. 4 is a cross-sectional view of a display device in the related art;

FIG. 5 is a cross-sectional view along the direction B-B′ shown in FIG. 1 according to some embodiments of the present disclosure;

FIG. 6 is a schematic planar structural diagram of a side of a backlight surface of the display panel of the display device shown in FIG. 1 according to some embodiments of the present disclosure;

FIG. 7 is a cross-sectional view along a direction C-C′ shown in FIG. 6 according to some embodiments of the present disclosure;

FIG. 8 is a schematic planar structural diagram of a side of a light-emitting surface of a display panel of a display device according to some embodiments of the present disclosure;

FIG. 9 is a schematic planar structural diagram of a side of a backlight surface of the display panel of the display device shown in FIG. 8 according to some embodiments of the present disclosure;

FIG. 10 is a cross-sectional view along the direction D-D′ shown in FIG. 8 according to some embodiments of the present disclosure;

FIG. 11 is an enlarged structural diagram of a connecting portion and a first conductive portion shown in FIG. 1 according to some embodiments of the present disclosure;

FIG. 12 is a cross-sectional view along the direction C-C′ shown in FIG. 6 according to some embodiments of the present disclosure;

FIG. 13 is a cross-sectional view along the direction C-C′ shown in FIG. 6 according to some embodiments of the present disclosure;

FIG. 14 is a cross-sectional view along the direction D-D′ shown in FIG. 8 according to some embodiments of the present disclosure;

FIG. 15 is a cross-sectional view along the direction C-C′ shown in FIG. 6 according to some embodiments of the present disclosure;

FIG. 16 is a cross-sectional view along the direction D-D′ shown in FIG. 8 according to some embodiments of the present disclosure;

FIG. 17 is a schematic planar structural diagram of a side of a light-emitting surface of a display panel of a display device according to some embodiments of the present disclosure;

FIG. 18 is a schematic planar structural diagram of a side of a backlight surface of the display panel of the display device shown in FIG. 17 according to some embodiments of the present disclosure;

FIG. 19 is a cross-sectional view long the direction E-E′ shown in FIG. 17 according to some embodiments of the present disclosure; and

FIG. 20 is a flowchart of a method for manufacturing a display device according to some embodiments of the present disclosure;

FIG. 21 is a structural schematic diagram of a display panel provided in the method of FIG. 20 according to some embodiments of the present disclosure;

FIG. 22 is a structural schematic diagram after manufacturing a support protective film on a side of a backlight surface of the display panel in the method of FIG. 20 according to some embodiments of the present disclosure;

FIG. 23 is a structural schematic diagram after manufacturing a first conductive adhesive in the method of FIG. 20 according to some embodiments of the present disclosure;

FIG. 24 is a structural schematic diagram after removing a support protective film in the method of FIG. 20 according to some embodiments of the present disclosure ;

FIG. 25 is a structural schematic diagram of a driving assembly provided in the method of FIG. 20 according to some embodiments of the present disclosure;

FIG. 26 is a structural schematic diagram after fixing the driving assembly and the display panel in the method of FIG. 20 according to some embodiments of the present disclosure;

FIG. 27 is a structural schematic diagram after manufacturing a second conductive adhesive in the method of FIG. 20 according to some embodiments of the present disclosure;

FIG. 28 is a flowchart of a method for manufacturing a display device according to some embodiments of the present disclosure;

FIG. 29 is a structural schematic diagram after manufacturing an encapsulation structure in the method of FIG. 28 according to some embodiments of the present disclosure;

FIG. 30 is a structural schematic diagram after manufacturing a second conductive adhesive in the method of FIG. 28 according to some embodiments of the present disclosure;

FIG. 31 is a structural schematic diagram after manufacturing a second conductive adhesive in the method of FIG. 20 according to some embodiments of the present disclosure;

FIG. 32 is a structural schematic diagram after manufacturing a second conductive adhesive in the method of FIG. 28 according to some embodiments of the present disclosure;

FIG. 33 is a flowchart of a method for manufacturing a display device according to some embodiments of the present disclosure; and

FIG. 34 is a structural schematic diagram after manufacturing a protective layer in the method of FIG. 33 according to some embodiments of the present disclosure.

### DESCRIPTION OF EMBODIMENTS

In order to more clearly understand the above-mentioned purposes, features and advantages of the present disclosure, the solutions of the present disclosure will be further described below. It should be noted that the embodiments of the present disclosure and features in the embodiments may be combined with each other without conflict.

In the following description, many specific details are set forth to fully understand the present disclosure, but the present disclosure may be implemented in other manners different from those described herein. It is apparent that the embodiments in the specification are merely a part of the embodiments of the present disclosure, not all of the embodiments of the present disclosure.

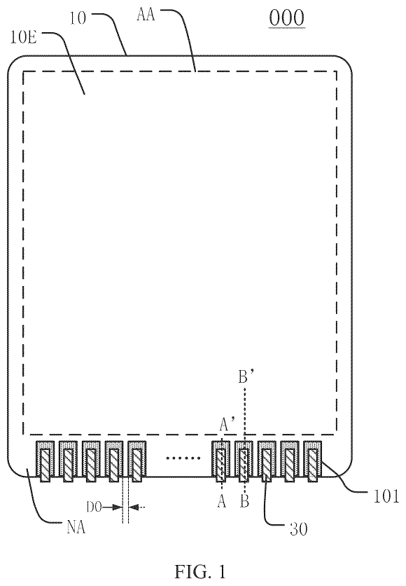

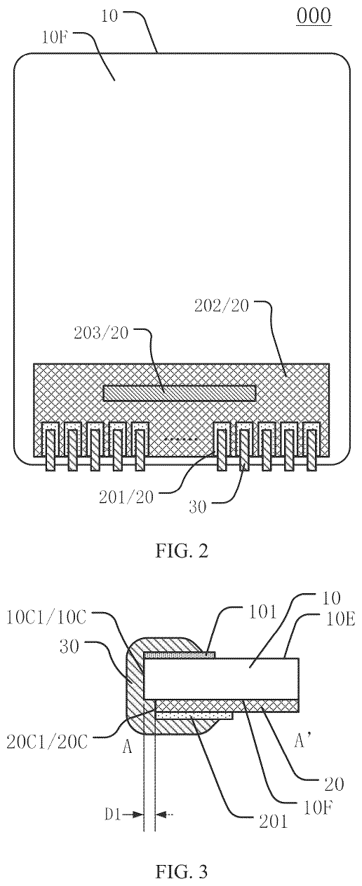

Referring to FIG. 1 to FIG. 3, FIG. 1 is a schematic planar structural diagram of a side of a light-emitting surface of a display panel of a display device according to some embodiments of the present disclosure, FIG. 2 is a schematic planar structural diagram of a side of a backlight surface of the display panel of the display device shown in FIG. 1, FIG. 3 is a cross-sectional view along the direction A-A′ shown in FIG. 1. In some embodiments, the display device 000 includes a display panel 10 (not filled in the drawings) and a driving assembly 20. The display panel 10 includes a light-emitting surface 10E and a backlight surface 10F opposite to each other, and the driving assembly 20 is located on a side of the backlight surface 10F of the display panel 10.

A side of the light-emitting surface 10E of the display panel 10 includes a plurality of first conductive portions 101, and a side of the driving assembly 20 away from the display panel 10 includes a plurality of second conductive portions 201.

The display device 000 further includes a plurality of connecting portions 30. The connecting portion at least covers a surface of a side of the first conductive portion 101 away from the second conductive portion 201, a surface of a side of the second conductive portion 201 away from the first conductive portion 101, a side surface 10C of the display panel 10, and a side surface 20C of the driving assembly 20.

The first conductive portion 101 is electrically connected to the second conductive portion 201 through the connecting portion 30.

For example, in some embodiments, the display device 000 includes the display panel 10 and the driving assembly 20. The display panel 10 may be either one of a flexible display panel or a rigid display panel. For example, the display panel 10 may be a flexible OLED display panel or a rigid OLED display panel, which is not limited in the embodiments. The driving assembly 20 may be a structure for providing a driving signal, such as a driving chip and/or a flexible circuit board, and is configured to be electrically connected to the display panel 10 to provide a driving signal for the display panel 10, so as to achieve the display function of the display panel, and the like. In some embodiments, the display panel 10 includes a light-emitting surface 10E and a backlight surface 10F opposite to each other. The light-emitting surface 10E of the display panel 10 may be understood as a surface on which sub-pixels in the display region AA of the display panel 10 emit light, or may also be understood as a surface on which a user views a displayed image. The backlight surface 10F of the display panel 10 may be understood as another side surface of the display panel 10 opposite to the light-emitting surface 10E. It may be understood that, in some embodiments, the side surface 10C of the display panel 10 mentioned subsequently may be understood as that the display panel 10 has a certain thickness, and a side edge of the display panel 10 may be understood as the side surface 10C of the display panel 10. In some embodiments, the side surface 20C of the driving assembly 20 mentioned subsequently may be understood as that the driving assembly 20 has a certain thickness, and a side edge of the driving assembly 20 may be understood as the side surface 20C of the driving assembly 20. Details are not elaborated in the embodiments of the present disclosure.

In some embodiments, the driving assembly 20 is located on a side of the backlight surface 10F of the display panel 10. The driving assembly 20 located on the backlight surface 10F of the display panel 10 is electrically connected to a signal trace located on the side of the light-emitting surface 10E of the display panel 10 through the first conductive portion 101 and the second conductive portion 201. For example, a side of the light-emitting surface 10E of the display panel 10 includes a plurality of first conductive portions 101. The first conductive portions 101 may be located in a non-display region NA of the display panel 10 (as shown in FIG. 1). The non-display region NA is at least partially arranged around the display region AA, and the display region AA is used for arranging sub-pixels of the display panel 10 (not shown in the drawings). The side of the driving assembly 20 away from the display panel 10 includes a plurality of second conductive portions 201. In some embodiments, the first conductive portions 101 may be in one-to-one correspondence with the second conductive portions 201. That is, the number of the plurality of first conductive portions 101 included on the side of the light-emitting surface 10E of the display panel 10 may be the same as the number of the plurality of second conductive portions 201 included on the side of the driving assembly 20 away from the display panel 10, or the number of the first conductive portions 101 included on the side of the light-emitting surface 10E of the display panel 10 may be less than the number of the second conductive portions 201 included on the side of the driving assembly 20 away from the display panel 10, which is not limited in the embodiments. In specific implementation, the design may be made according to the structure of the driving assembly 20, which is not described herein.

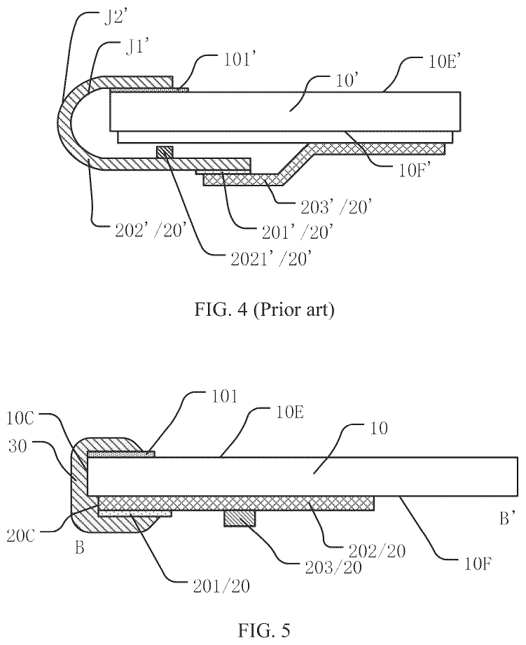

In the related art, if the driving assembly includes a Chip-on-film/Flex (COF) structure and a flexible circuit board, that is, the driving assembly includes the chip-on-film structure (the chip-on-film structure may be understood as a die soft-film structure in which a driving chip is directly mounted on the flexible circuit board) and the flexible circuit board, the bending technology is adopted to narrow the bezel width of the display panel. As shown in FIG. 4, FIG. 4 is a cross-sectional view of a display device provided in the related art. A side of a light-emitting surface 10E′ of a display panel 10′ in the related art includes a plurality of first conductive portions 101′. One end of a chip-on-film 202′ of a driving assembly 20′ is bonded and electrically connected to the first conductive portion 101′ of the display panel 10′ on a side of the light-emitting surface 10E′ of the display panel 10′. After the chip-on-film 202′ of the driving assembly 20′ is bent to a side of a backlight surface 10F′ of the display panel 10′, the other end of the chip-on-film 202′ is bonded and electrically connected to a flexible circuit board 203′ through a second conductive portion 201′ of the driving assembly 20′, thereby realizing that a driving signal provided by the flexible circuit board 203′ located on the side of the backlight surface 10F′ of the display panel 10′ is transmitted to the first conductive portion 101′ on the side of the light-emitting surface 10E′ of the display panel 10′ through the bent chip-on-film 202′, so as to realize the display function of the display panel. As can be seen from FIG. 3, the bending of the chip-on-film 202′ of the driving assembly 20′ can prevent the structure of the driving assembly 20′ from occupying excessive bezel space on the side of the light-emitting surface 10E′ of the display panel 10′ and improve the screen-to-body ratio, but the bent portion of the chip-on-film 202′ is prone to cracks, and the size of the bent region of the chip-on-film 202′ is unstable, thereby easily causing various problems such as open circuits, poor size, and unreliable bending strength (the same problem will arise if the bending technology for flexible display panels is adopted). In addition, the first surface of the chip-on-film 202′ of the driving assembly 20′ in FIG. 3 (such as a J1′ surface in FIG. 4) generally needs to be provided with a conductive layer to be bonded and electrically connected to the first conductive portion 101′ of the display panel 10′. As a result, the reasonable arrangement structure is that the first surface of the chip-on-film 202′ mounts a driving chip 2021′ included therein by using the conductive layer. However, the second surface of the chip-on-film 202′ (such as a J 2′ surface in FIG. 4), that is, a side away from the display panel 10′, also needs to be bonded to the flexible circuit board 203′ through the second conductive portion 201′. That is, the chip-on-film 202′ adopted in the driving assembly 20′ inevitably requires a structural design of double-sided conductive layers (both the J1′ surface and the J2′ surface need to be provided with the conductive layer), resulting in a substantial increase in cost.

To solve the above problems, the display device 000 according to the embodiments of the present disclosure further includes a plurality of connecting portions 30. The connecting portion 30 at least covers a surface of a side of the first conductive portion 101 away from the second conductive portion 201, a surface of a side of the second conductive portion 201 away from the first conductive portion 101, a side surface 10C of the display panel 10, and a side surface 20C of the driving assembly 20. That is, the connecting portion 30 may be at least understood as an integrated structure with four segments. As shown in FIG. 3, one segment of the connecting portion 30 at least partially covers the surface of the side of the first conductive portion 101 away from the second conductive portion 201, one segment of the connecting portion 30 at least partially covers the side surface 10C of the display panel 10, one segment of the connecting portion 30 at least partially covers the side surface 20C of the driving assembly 20, and one segment of the connecting portion 30 at least partially covers the surface of the side of the second conductive portion 201 away from the first conductive portion 101. The first conductive portion 101 is electrically connected to the second conductive portion 201 through the connecting portion 30. After a signal trace in a layer structure (such as metal layers including a driving array layer) of the display panel 10 is electrically connected to the first conductive portion 101 on a side of the light-emitting surface 10E of the display panel 10, electrical signal transmission can be achieved with the second conductive portion 201 of the driving assembly 20 on a side of the backlight surface 10F of the display panel 10 through the connecting portion 30.

In some embodiments, the driving assembly 20 is completely arranged on a side of the backlight surface 10F of the display panel 10, so that the driving assembly 20 does not occupy the bezel space on a side of the light-emitting surface 10E of the display panel 10, thereby further improving the screen-to-body ratio. In addition, the side of the driving assembly 20 away from the display panel 10 includes a plurality of second conductive portions 201, that is, the driving assembly 20 is of a single-sided structure, and the second conductive portions 201 are arranged only on the side away from the display panel 10. The driving chips or the bonded flexible circuit boards of the other driving assemblies 20 may be arranged on the same side of the second conductive portions 201, which avoids cost increase when the driving assembly 20 is configured as a double-sided structure (that is, conductive layers are provided on both the side of the driving assembly away from the display panel and the side of the driving assembly facing the display panel), thereby saving the consumption cost of the driving assembly 20.

In some embodiments, when the first conductive portion 101 is electrically connected to the second conductive portion 201, a connecting portion 30 is provided, and the connecting portion 30 at least covers the surface of the side of the first conductive portion 101 away from the second conductive portion 201, the surface of the side of the second conductive portion 201 away from the first conductive portion 101, the side surface 10C of the display panel 10, and the side surface 20C of the driving assembly 20. The connecting portions 30 may be arranged in one-to-one correspondence with the first conductive portions 101 and the second conductive portions 201, that is, one connecting portion 30 is correspondingly electrically connected to one first conductive portion 101 and one second conductive portion 201, so as to realize electrical signal transmission between the first conductive portion 101 on a side of the light-emitting surface 10E of the display panel 10 and the second conductive portion 201 on a side of the driving assembly 20 away from the display panel 10. In some embodiments, the driving assembly 20 is completely arranged on a side of the backlight surface 10F of the display panel 10, so that the driving assembly 20 does not occupy the bezel space on a side of the light-emitting surface 10E of the display panel 10, thereby improving the screen-to-body ratio. According to the display device 000 of the embodiments of the present disclosure, after the driving assembly 20 is completely arranged on a side of the backlight surface 10F of the display panel 10, it is equivalent to canceling the bending design of the driving assembly 20, and the electrical signal transmission between the display panel 10 and the driving assembly 20 can be realized, which can effectively prevent the problems that cracks caused by bending lead to breakage of internal traces of the driving assembly 20 and unreliable bending strength, thereby affecting the display quality and the process yield. In addition, after canceling the bending design of the driving assembly, the bezel space of the display device originally occupied by the bent portion of the driving assembly 20 will also disappear, leaving only the width occupied by the connecting portion 30 on the side surface 10C of the display panel 10 and the side surface 20C of the driving assembly 20. In some embodiments, the connecting portion 30 may be coated to cover the surface of the side of the first conductive portion 101 away from the second conductive portion 201, the surface of the side of the second conductive portion 201 away from the first conductive portion 101, the side surface 10C of the display panel 10, and the side surface 20C of the driving assembly 20. Therefore, the width occupied by the connecting portion 30 on the side surface 10C of the display panel 10 and the side surface 20C of the driving assembly 20 is greatly reduced as compared with the bezel width occupied when the driving assembly is bent to a side of the backlight surface of the display panel in the related art, thereby facilitating further realizing the narrow-bezel or even bezel-less effect, effectively avoiding the problems such cracks or open circuits, achieving the reliability of the electrical connection between the driving assembly 20 and the display panel 10, and improving the display quality and the process yield.

It should be noted that the specific structure of the display panel 10 is not described in detail in the embodiments of the present disclosure, and understanding may be made with reference to structures of organic light-emitting display panels in the related art. In some embodiments, FIG. 2 only illustrates an example in which the driving assembly 20 is designed as a chip-on-film structure. In specific implementation, the driving assembly 20 may also be other structures, which may be understood with reference to the description of the subsequent embodiments for details and is not described herein.

In some embodiments, as shown in FIG. 1 and FIG. 5, FIG. 5 is a cross-sectional view along the direction B-B′ shown in FIG. 1. The driving assembly 20 in the embodiments of the present disclosure may adopt a COF technology. For example, the driving assembly 20 may include a chip-on-film. The chip-on-film itself includes a first flexible circuit board 202 and a driving chip 203 mounted thereto. A side of the first flexible circuit board 202 away from the display panel 10 includes a second conductive portion 201 and the driving chip 203, and the second conductive portion 201 is electrically connected to the driving chip 203 through an internal circuit of the first flexible circuit board 202 to transmit an electrical signal. The driving chip 203 and the second conductive portion 201 may be arranged on the same side surface of the first flexible circuit board 202. That is, the chip-on-film adopted in the driving assembly 20 may be designed as only a single-sided conductive layer, which can effectively save cost.

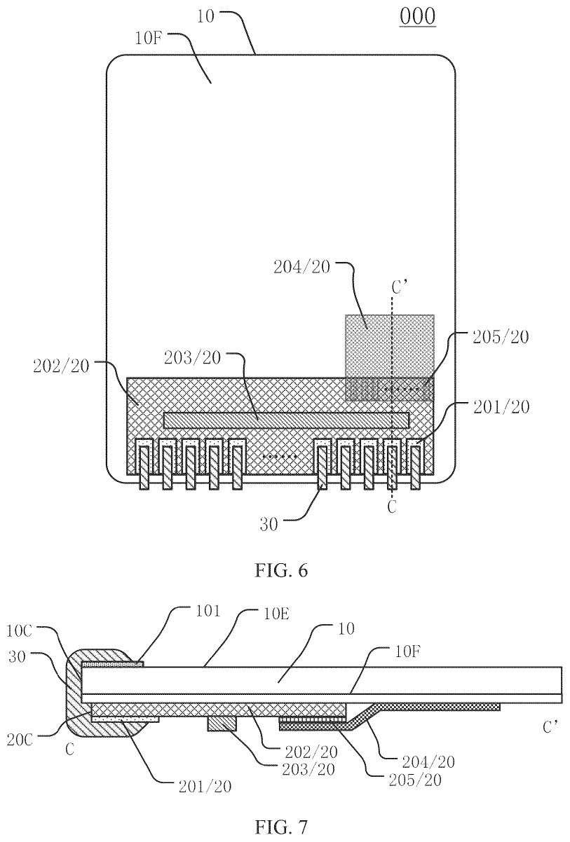

Further, in some embodiments, as shown in FIG. 1, FIG. 6 and FIG. 7, FIG. 6 is a schematic planar structural diagram of a side of a backlight surface of the display panel of the display device shown in FIG. 1, and FIG. 7 is a cross-sectional view along the direction C-C′ shown in FIG. 6 (it may be understood that in order to clearly illustrate the structure of the embodiments, transparency filling is performed in FIG. 6). In some embodiments, the driving assembly 20 may a chip-on-film and a second flexible circuit board 204. The chip-on-film itself includes a first flexible circuit board 202 and a driving chip 203 mounted thereto. A side of the first flexible circuit board 202 away from the display panel 10 includes a second conductive portion 201 and the driving chip 203, and the second conductive portion 201 is electrically connected to the driving chip 203 through an internal circuit of the first flexible circuit board 202 to transmit an electrical signal. The side of the first flexible circuit board 202 away from the display panel 10 further includes third conductive portion 205. The second flexible circuit board 204 may be electrically connected to the first flexible circuit board 202 of the chip-on-film through the third conductive portion 205, thereby achieving the purpose of transmitting the driving signal provided by the second flexible circuit board 204 through the chip-on-film and the display panel 10.

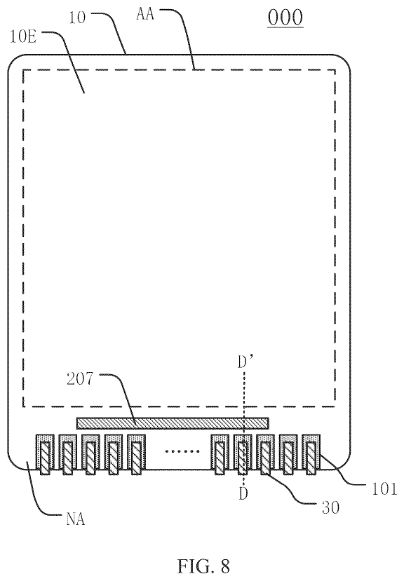

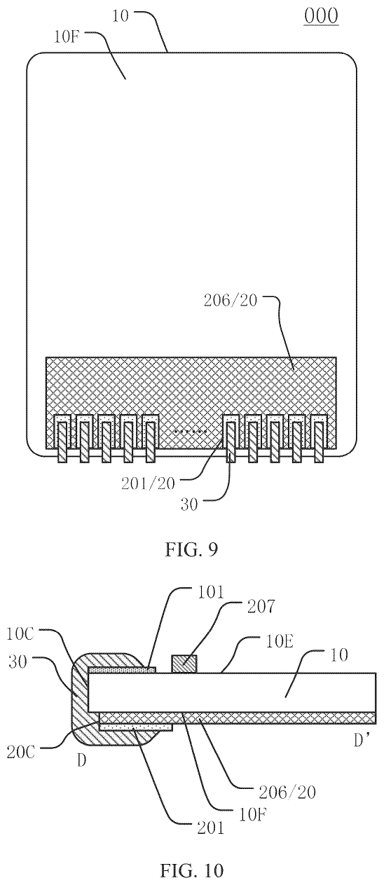

In some embodiments, as shown in FIG. 8, FIG. 9 and FIG. 10, FIG. 8 is a schematic planar structural diagram of a side of a light-emitting surface of a display panel of a display device according to some embodiments of the present disclosure, FIG. 9 is a schematic planar structural diagram of a side of a backlight surface of the display panel of the display device shown in FIG. 8, and FIG. 10 is a cross-sectional view along the direction D-D′ shown in FIG. 8. In some embodiments, the driving assembly 20 may adopt a chip on glass (COG) technology (that is, a driving chip is directly bound on a substrate of the display panel). The driving assembly 20 in the embodiments of the present disclosure includes a flexible circuit board 206 located on a side of the backlight surface 10F of the display panel 10. A side of the flexible circuit board 206 away from the display panel 10 includes a plurality of second conductive portions 201. A side of the light-emitting surface 10E of the display panel 10 includes a driving chip 207. The driving chip 207 is electrically connected to the flexible circuit board 206 through the first conductive portion 101, the connecting portion 30, and the second conductive portion 201. The driving chip 207 is directly bound and electrically connected to the display panel 10 on a side of the light-emitting surface 10E of the display panel 10. The driving chip 207 may be electrically connected to the first conductive portion 101 through a signal line in the non-display region NA of the display panel 10. The first conductive portion 101 is electrically connected to the second conductive portion 201 on a side of the backlight surface 10F of the display panel 10 through the connecting portion 30. Accordingly, the driving signals provided by the flexible circuit board 206 of the driving assembly 20 can be transmitted to the display panel 10 through the second conductive portion 201, the connecting portion 30, the first conductive portion 101, and the driving chip 207, so as to drive the display panel to display images. In some embodiments, when the display panel 10 is electrically connected to the driving assembly 20, the COG technology is adopted. After the driving signals required for the display of the display panel 10 are processed by the driving chip 207, the number of the signal terminals, i.e., the first conductive portions 101, can be greatly reduced, so that the number of the first conductive portions 101 arranged on a side of the light-emitting surface 10E of the display panel 10 can be greatly reduced, which can better realize mass production. Since the number of the first conductive portions 101 is reduced, the mutual short circuit between the first conductive portions 101 can be avoided by increasing the spacing between the first conductive portions 101, thereby achieving the process yield. In addition, in some embodiments, the structure that the first conductive portion 101 is electrically connected to the second conductive portion 201 through the connecting portion 30 can compensate for the increased bezel width caused by disposing the driver chip 207 in the non-display region on a side of the light-emitting surface 10E of the display panel 10, and can still effectively realize the narrow-bezel design of the display device.

In some embodiments, as shown in FIG. 1 to FIG. 3, a material of the first conductive portion 101 arranged on a side of the light-emitting surface 10E of the display panel 10 includes metallic titanium, and a material of the second conductive portion 201 arranged on the side of the driving assembly 20 away from the display panel 10 includes metallic copper. The first conductive portion 101 is manufactured in a conductive layer of the display panel 10, and may be formed by a mask evaporation process. The second conductive portion 201 of the driving assembly 20, that is, the second conductive portion 201 on the flexible circuit board, may be manufactured by etching a metallic copper layer. Accordingly, the first conductive portion 101 may be manufactured using a metallic titanium layer of the display panel 10, and the second conductive portion 201 may be manufactured using a metallic copper layer of the flexible circuit board of the driving assembly 20, thereby saving the manufacturing cost and reducing the process difficulty.

In some embodiments, as shown in FIG. 1 to FIG. 3, the material of the connecting portion 30 includes a conductive adhesive material containing metallic silver and metallic copper. Using the conductive adhesive material doped with metallic silver and metallic copper as the connecting portion 30 can achieve the conductivity of the connecting portion 30, and can also achieve the adhesion of the connecting portion 30 when the connecting portion 30 is coated on the surface of the side of the first conductive portion 101 away from the second conductive portion 201, the surface of the side of the second conductive portion 201 away from the first conductive portion 101, the side surface 10C of the display panel 10, and the side surface 20C of the driving assembly 20, thereby facilitating improving the reliability of the electrical connection.

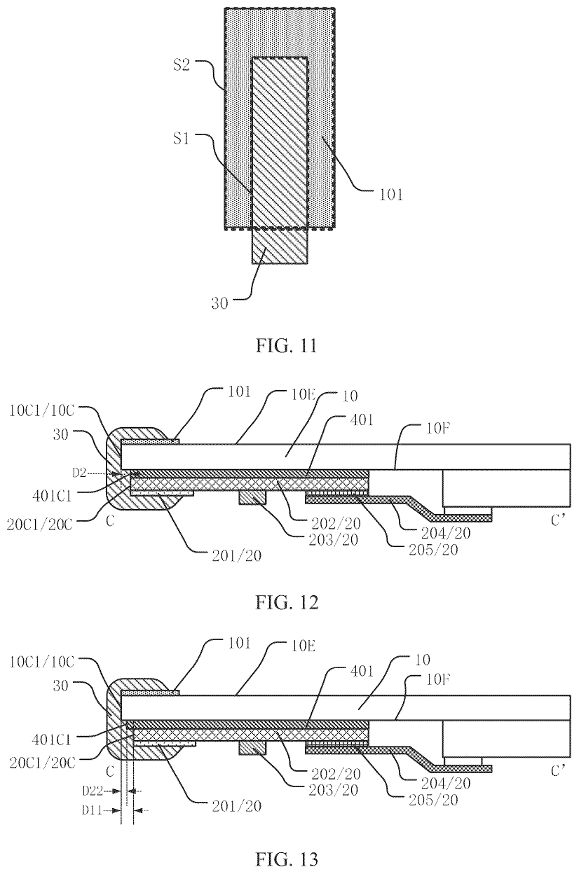

In some embodiments, referring to FIG. 1 to FIG. 3 and FIG. 11, FIG. 11 is an enlarged structural diagram of the connecting portion and the first conductive portion shown in FIG. 1. In some embodiments, the area of the connecting portion 30 covering the first conductive portion 101 is S1, and the orthographic projection area of the first conductive portion 101 on the plane of the display panel 10 is S2, where 0.6S2≤S1≤0.8 S2. It should be noted that, in some embodiments, the plane of the display panel 10 may be understood as the plane where the overall macroscopic structure of the display panel 10 is located, or may be understood as the plane where a base substrate of the display panel 10 is located.

Some embodiments illustrates that, when the first conductive portion 101 on a side of the light-emitting surface 10E of the display panel 10 is electrically connected to the second conductive portion 201 on the side of the driving assembly 20 away from the display panel 10 through the connecting portion 30, if the orthographic projection area of the first conductive portion 101 on the plane of the display panel 10 is S2, and the area of the connecting portion 30 at least partially covering the first conductive portion 101 is S1, then S1 is less than S2. The area of the connecting portion 30 covering the first conductive portion 101 is smaller than the area of the first conductive portion 101 itself. The area S1 of the connecting portion 30 covering the first conductive portion 101 is set to be relatively small, and smaller than the area of the first conductive portion 101 itself, which can prevent the connecting portion 30 from encroaching on the space between adjacent first conductive portions 101 when the connecting portion 30 is coated on the surface of the first conductive portion 101, resulting in a short circuit between the adjacent first conductive portions 101. In addition, considering that, during a process procedure, the coating process of the connecting portion 30 may be defective and require rework and recoating, 0.6S2≤S1≤0.8 S2 can be set. That is, the area S1 of the connecting portion 30 covering the first conductive portion 101 is about 60% to 80% of the area of the first conductive portion 101, so as to avoid the problems of reliability of electrical connection caused by the excessively small covering area of the connecting portion 30 on the first conductive portion 101, to achieve the reliability of electrical connection between the connecting portion 30 and the first conductive portion 101, and to avoid the problems of short circuit caused by the excessively large covering area of the connecting portion 30 on the first conductive portion 101, effectively preventing a short circuit between adjacent first conductive portions 101 and effectively preventing a short circuit between adjacent connecting portions 30, and also facilitating the re-coating of the connecting portions 30, thereby improving the process efficiency.

It can be understood that, as shown in FIG. 2, in some embodiments, the area of the connecting portion 30 covering the second conductive portion 201 on the side of the driving assembly 20 away from the display panel 10 may also be set to be smaller than the orthographic projection area of the second conductive portion 201 on the plane of the display panel 10, and the area of the second conductive portion 201 of which the area of the connecting portion 30 covering the second conductive portion 201 on the side of the driving assembly 20 away from the display panel 10 is about 60% to 80% of the area of the second conductive portion 201, so as to avoid the problems of reliability of electrical connection caused by the excessively small covering area of the connecting portion 30 on the second conductive portion 201, to achieve the reliability of electrical connection between the connecting portion 30 and the second conductive portion 201, and to avoid the problems of short circuit caused by the excessively large covering area of the connecting portion 30 on the second conductive portion 201, effectively preventing a short circuit between adjacent second conductive portions 201 and effectively preventing a short circuit between adjacent connecting portions 30, and also facilitating the re-coating of the connecting portions 30, thereby improving the process efficiency.

In some embodiments, continuing to refer to FIG. 1 to FIG. 3, along the arrangement direction of the first conductive portions 101, a distance between two adjacent first conductive portions 101 is D0, where 30 μm≤D0≤100 μm.

Some embodiments illustrates that, when the first conductive portion 101 on a side of the light-emitting surface 10E of the display panel 10 is electrically connected to the second conductive portion 201 on the side of the driving assembly 20 away from the display panel 10 through the connecting portion 30, the distance D0 between adjacent first conductive portions 101 may be relatively reduced. For example, the minimum distance D0 between adjacent first conductive portions 101 may be 30 μm, so that a larger number of first conductive portions 101 may be arranged within the same size range. Since the area of the connecting portion 30 covering the first conductive portion 101 is set to be smaller than the area of the first conductive portion 101, even if the gap between adjacent first conductive portions 101 is relatively small, a certain spacing may still be achieved between corresponding connecting portions 30, making short circuits unlikely to occur. Therefore, when applied to the COF technology (as shown in the embodiments of FIG. 6 and FIG. 7), as many first conductive portions 101 as possible are arranged in the non-display region NA on a side of the light-emitting surface 10E of the display panel 10, so as to meet the binding requirements between a relatively large number of signal terminals of the chip-on-film and the first conductive portions 101. Similarly, the distance D0 between two adjacent first conductive portions 101 may be 100 μm. In this case, the display panel 10 may be electrically connected to the driving assembly 20 by adopting the COG technology (as shown in the embodiments of FIG. 8 to FIG. 10). Since the number of the first conductive portions 101 on a side of the light-emitting surface 10E of the display panel 10 may be greatly reduced after adopting the COG technology, the distance between adjacent first conductive portions 101 may be set to be relatively large, facilitating the coating and covering of the connecting portions 30, reducing the process difficulty of the coating process, improving the process efficiency, and better meeting the mass production requirements.

In some embodiments, continuing to refer to FIG. 1 to FIG. 3 and FIG. 5 to FIG. 10, the side surface 10C of the display panel 10 includes a first edge 10C1 facing the connecting portion, and the side surface 20C of the driving assembly 20 includes a second edge 20C1 facing the connecting portion 30.

Along a direction parallel to the plane of the display panel 10, the distance from the second edge 20C1 to the first edge 10C1 is D1, where D1>0.

In some embodiments, when the driving assembly 20 is entirely arranged on a side of the backlight surface 10F of the display panel 10, the driving assembly 20, such as the first flexible circuit board 202 of the chip-on-film as shown in FIG. 5 and FIG. 7 or the flexible circuit board 206 as shown in FIG. 10, is retracted inward relative to the first edge 10C1 of the display panel 10. That is, the second edge 20C1, which is included in the side surface 20C of the driving assembly 20 and faces the connecting portion 30, and the first edge 10C1 of the display panel 10 form a certain step-shaped structure, thereby facilitating the coating of the connecting portion 30 on the side surface 10C of the display panel 10 and the side surface 20C of the driving assembly 20, and achieving the product yield.

In some embodiments, referring to FIG. 1, FIG. 6 and FIG. 12, FIG. 12 is a cross-sectional view along the direction C-C′ shown in FIG. 6. In some embodiments, a first pressure sensitive adhesive layer 401 is provided between the display panel 10 and the driving assembly 20, and a side of the backlight surface 10F of the display panel 10 is fixed to the driving assembly 20 through the first pressure sensitive adhesive layer 401.

In some embodiments, when the driving assembly 20 is entirely arranged on a side of the backlight surface 10F of the display panel 10, the first pressure sensitive adhesive layer 401 (Pressure Sensitive Adhesives, PSA) is arranged on a side of the backlight surface 10F of the display panel 10. The adhesive fixing between the backlight surface 10F of the display panel 10 and the driving assembly 20 can be realized by applying slight pressure, without heating, solvents or other complex curing processes, which simplifies the process steps and improves the process efficiency.

In some embodiments, as shown in FIG. 12, the side surface 10C of the display panel 10 includes a first edge 10C1 facing the connecting portion 30, and the side surface of the first pressure sensitive adhesive layer 401 includes a third edge 401C1 facing the connecting portion 30.

Along the direction parallel to the plane of the display panel 000, the distance from the third edge 401C1 to the first edge 10C1 is D2, where D2>0.

In some embodiments, when the driving assembly 20 is entirely arranged on a side of the backlight surface 10F of the display panel 10, and the adhesive fixing between the display panel 10 and the driving assembly 20 are achieved through the first pressure sensitive adhesive layer 401, the side surface 10C of the display panel 10 includes the first edge 10C1 facing the connecting portion 30, and the side surface of the first pressure sensitive adhesive layer 401 includes the third edge 401C1 facing the connecting portion 30. Along the direction parallel to the plane of the display panel 000, the distance D2 from the third edge 401C1 to the first edge 10C1 is greater than 0. The third edge 401C1 of the first pressure sensitive adhesive layer 401 is retracted inward relative to the first edge 10C1 of the display panel 10. That is, the third edge 401C1 of the first pressure sensitive adhesive layer 401 and the first edge 10C1 of the display panel 10 form a certain step-shaped structure, thereby facilitating the coating of the connecting portion 30 on the side surface 10C of the display panel 10 and one the third edge 401C1 of the first pressure sensitive adhesive layer 401, and achieving the product yield.

In some embodiments, referring to FIG. 1, FIG. 6 and FIG. 13, FIG. 13 is a cross-sectional view along the direction C-C′ shown in FIG. 6. In some embodiments, the side surface 10C of the display panel 10 includes the first edge 10C1 facing the connecting portion 30, the side surface 20C of the driving assembly 20 includes the second edge 20C1 facing the connecting portion 30, and the side surface of the first pressure sensitive adhesive layer 401 includes the third edge 401C1 facing the connecting portion 30.

Along the direction parallel to the plane of the display panel 000, the distance from the second edge 20C1 to the first edge 10C1 is D11, and the distance from the third edge 401C1 to the first edge 10C1 is D22, where D11≥D22.

In some embodiments, when the driving assembly 20 is entirely arranged on a side of the backlight surface 10F of the display panel 10, and the adhesive fixing between the display panel 10 and the driving assembly 20 are achieved through the first pressure sensitive adhesive layer 401, the side surface 10C of the display panel 10 includes the first edge 10C1 facing the connecting portion 30, the side surface 20C of the driving assembly 20 includes the second edge 20C1 facing the connecting portion 30, and the side surface of the first pressure sensitive adhesive layer 401 includes the third edge 401C1 facing the connecting portion 30. The first edge 10C1 of the display panel 10, the third edge 401C1 of the first pressure sensitive adhesive layer 401, and the second edge 20C1 of the driving assembly 20 form a certain step-shaped structure. That is, the third edge 401C1 of the first pressure sensitive adhesive layer 401 is retracted inward relative to the first edge 10C1 of the display panel 10, and the second edge 20C1 of the driving assembly 20 is retracted inward relative to or flush with the third edge 401C1 of the first pressure sensitive adhesive layer 401. Along the direction parallel to the plane of the display panel 000, the distance D11 from the second edge 20C 1 to the first edge 10C1 is greater than or equal to the distance D22 from the third edge 401C1 to the first edge 10C1, thereby facilitating the coating of the connecting portion 30 on the side surface 10C of the display panel 10, the third edge 401 of the first pressure-sensitive adhesive layer 401, and the side surface 20C of the driving assembly 20, and achieving the product yield.

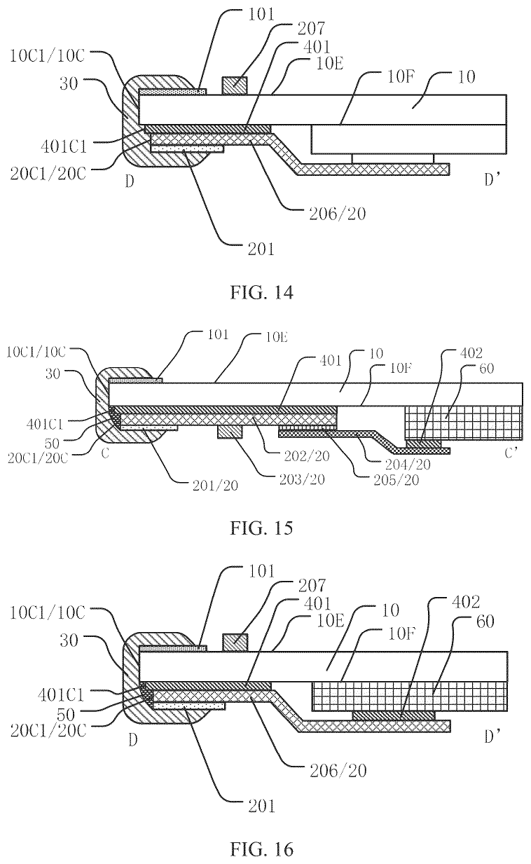

FIG. 14 is a cross-sectional view along the direction D-D′ shown in FIG. 8. In some embodiments, referring to FIG. 8, FIG. 9, and FIG. 14, the driving assembly 20 may adopt the COG technology, that is, the driving assembly 20 includes a flexible circuit board 206 located on a side of the backlight surface 10F of the display panel 10. A side of the flexible circuit board 206 away from the display panel 10 includes a plurality of second conductive portions 201. A side of the light-emitting surface 10E of the display panel 10 includes a driving chip 207. The driving chip 207 is electrically connected to the flexible circuit board 206 through the first conductive portion 101, the connecting portion 30, and the second conductive portion 201. The driving chip 207 is directly bound and electrically connected to the display panel 10 on a side of the light-emitting surface 10E of the display panel 10. The driving chip 207 may be electrically connected to the first conductive portion 101 through a signal line in the non-display region NA of the display panel 10. The first conductive portion 101 is electrically connected to the second conductive portion 201 on a side of the backlight surface 10F of the display panel 10 through the connecting portion 30. Accordingly, the driving signals provided by the flexible circuit board 206 of the driving assembly 20 can be transmitted to the display panel 10 through the second conductive portion 201, the connecting portion 30, the first conductive portion 101, and the driving chip 207, so as to drive the display panel to display images. The first pressure sensitive adhesive layer 401 may also be arranged between the flexible circuit board 206 and the backlight surface 10F of the display panel 10. The adhesive fixing between the backlight surface 10F of the display panel 10 and the flexible circuit board 206 of the driving assembly 20 can be realized by applying slight pressure, without heating, solvents or other complex curing processes, which simplifies the process steps and improves the process efficiency. In this case, the first edge 10C1 of the display panel 10, the third edge 401C1 of the first pressure sensitive adhesive layer 401, and the second edge 20C1 of the driving assembly 20 may also form a certain step-shaped structure. That is, the third edge 401C1 of the first pressure sensitive adhesive layer 401 is retracted inward relative to the first edge 10C1 of the display panel 10, and the second edge 20C1 of the driving assembly 20 is retracted inward relative to or flush with the third edge 401C1 of the first pressure sensitive adhesive layer 401, thereby facilitating the coating of the connecting portion 30, and achieving the product yield.

FIG. 15 is a cross-sectional view along the direction C-C′ shown in FIG. 6, and FIG. 16 is a cross-sectional view along the direction D-D′ shown in FIG. 8. In some embodiments, referring to FIG. 1, FIG. 6, FIG. 8, FIG. 9, FIG. 15, and FIG. 16, an encapsulation structure 50 is filled between the side surface of the first pressure sensitive adhesive layer 401 and the connecting portion 30, and between the side surface 20C of the driving assembly 20 and the connecting portion 30. The surface of the encapsulation structure 50 facing the connecting portion 30 is a smooth arc surface.

Some embodiments illustrates that, the first edge 10C1 of the display panel 10, the third edge 401C1 of the first pressure sensitive adhesive layer 401, and the second edge 20C1 of the driving assembly 20 form a certain step-shaped structure. To avoid that the step-segment structure causes corners in a region where the connecting portion 30 is coated, the encapsulation structure 50 may be filled between the side surface of the first pressure sensitive adhesive layer 401 and the connecting portion 30, and between the side surface 20C of the driving assembly 20 and the connecting portion 30. The encapsulation structure 50 may achieve that a uniform thickness can be formed when the connecting portion 30 is coated on the side surface of the first pressure sensitive adhesive layer 401 and the side surface of the driving assembly 20. In addition, the surface of the encapsulation structure 50 facing the connecting portion 30 is a smooth arc surface, which can further enable the connecting portion 30 to be tightly coated and cured on the smooth arc surface of the encapsulation structure 50, thereby avoiding the formation of cavities between the connecting portion 30 and the encapsulation structure 50, and achieving the process reliability of the product. In addition, the exposed outer surface of the connecting portion 30 can finally be formed smoothly, and corners of the display device can have fewer sharp structures, which achieves the product yield.

In some embodiments, referring to FIG. 1, FIG. 6, FIG. 8, FIG. 9, FIG. 15 and FIG. 16, a side of the backlight surface 10F of the display panel 10 further includes an ultra-clean foam composite film 60. The ultra-clean foam composite film 60 is independent of the first pressure sensitive adhesive layer 401, and the ultra-clean foam composite film 60 is located on a side of the first pressure sensitive adhesive layer 401 away from the edge of the display panel 10.

A side of the ultra-clean foam composite film 60 away from the light-emitting surface 10E of the display panel 10 is fixed to the driving assembly 20 through a second pressure sensitive adhesive layer 402.

Some embodiments illustrates that, the ultra-clean foam composite film 60 is further arranged on a side of the backlight surface 10F of the display panel 10. The ultra-clean foam composite film 60 may be understood as an Ultra-clean Foam (SCF) composite film, which can buffer stress acting on the display panel 10 and can dissipate heat generated when the display panel 10 operates, thereby providing a certain protective effect for the display panel 10. In some embodiments, the ultra-clean foam composite film 60 may include an adhesive layer, a buffer layer and a heat dissipation layer (not shown in the drawings) which are sequentially stacked and sequentially away from the display panel 10. The adhesive layer is made of Embo adhesive. The Embo adhesive is a mesh-pattern adhesive, which has functions of bonding and exhausting air during lamination. The buffer layer is made of foam, which can provide buffering. The heat dissipation layer is made of copper foil, which can provide functions of conduction, heat dissipation, and shielding. In some embodiments, the ultra-clean foam composite film 60 is independent of the first pressure sensitive adhesive layer 401, and the ultra-clean foam composite film 60 is located on a side of the first pressure sensitive adhesive layer 401 away from the edge of the display panel 10. A side of the ultra-clean foam composite film 60 facing the display panel 10 is directly attached and fixed to the backlight surface 10F of the display panel 10. The side of the ultra-clean foam composite film 60 away from the light-emitting surface 10E of the display panel 10 may be fixed to the driving assembly 20 through the second pressure sensitive adhesive layer 402. As shown in FIG. 15, when the driving assembly 20 adopts the COF technology, the side of the ultra-clean foam composite film 60 away from the light-emitting surface 10E of the display panel 10 may be fixed to the second flexible circuit board 204 of the driving assembly 20 through the second pressure sensitive adhesive layer 402. As shown in FIG. 16, when the driving assembly 20 adopts the COG technology, the side of the ultra-clean foam composite film 60 away from the light-emitting surface 10E of the display panel 10 may be fixed to the flexible circuit board 206 of the driving assembly 20 through the second pressure sensitive adhesive layer 402, so that the driving assembly 20 may be further better fixed to a side of the backlight surface 10F of the display panel 10, thereby further better fixing the driving assembly 20 on the side of the backlight surface 10F of the display panel 10 and achieving the connection stability between the driving assembly 20 and the display panel 10.

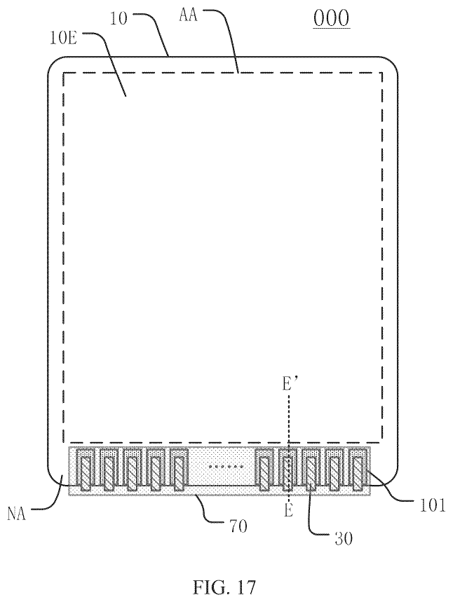

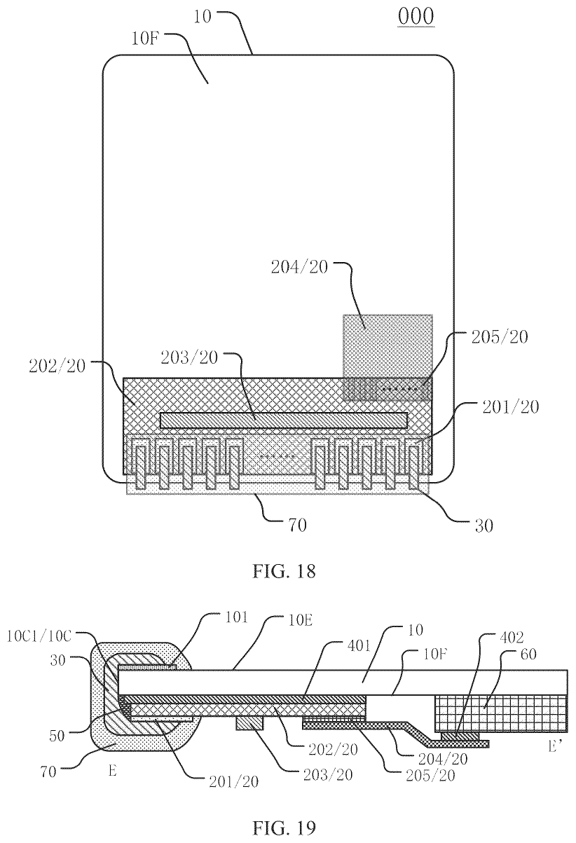

FIG. 17 is a schematic planar structural diagram of a side of a light-emitting surface of a display panel of a display device according to some embodiments of the present disclosure, FIG. 18 is a schematic planar structural diagram of a side of a backlight surface of the display panel of the display device shown in FIG. 17, and FIG. 19 is a cross-sectional view along the direction E-E′ shown in FIG. 17 (it may be understood that, in order to clearly illustrate the structure of the embodiments, transparency filling is performed in FIG. 17 and FIG. 18). In some embodiments, referring to FIG. 17, FIG. 18 and FIG. 19, the display device 000 further includes a protective layer 70, and the protective layer 70 wraps and covers the connecting portions 30.

In some embodiments, on a side of the light-emitting surface 10E of the display panel 10, the protective layer 70 covers at least part of the surface of the display panel 10.

On a side of the driving assembly 20 away from the display panel 10, the protective layer 70 covers at least part of the surface of the driving assembly 20.

Some embodiments illustrates that, when the first conductive portion 101 on a side of the light-emitting surface 10E of the display panel 10 is electrically connected to the second conductive portion 201 on a side of the driving assembly 20 away from the display panel 10 through the connecting portion 30, the protective layer 70 may be arranged to cover the connecting portions 30. For example, the protective layer 70 covers at least part of the surface of the display panel 10 on a side of the light-emitting surface 10E of the display panel 10, and the protective layer 70 covers at least part of the surface of the driving assembly 20 on a side of the driving assembly 20 away from the display panel 10, thereby enabling the protective layer 70 to wrap and cover the connecting portions 30. The protective layer 70 may be subjected to ordinary UV curing using an acrylic material, or UV curing and moisture curing using an acrylic material in combination, so that the protective layer 70 covering the connecting portions 30 may have effects of preventing corrosion of the connecting portions 30 caused by moisture permeation and protecting the connecting portions 30 from impact, and the protective layer 70 may prevent conductive materials such as the connecting portions 30 from being affected by external static electricity, moisture, grease, impact, and the like, thereby improving the product reliability.

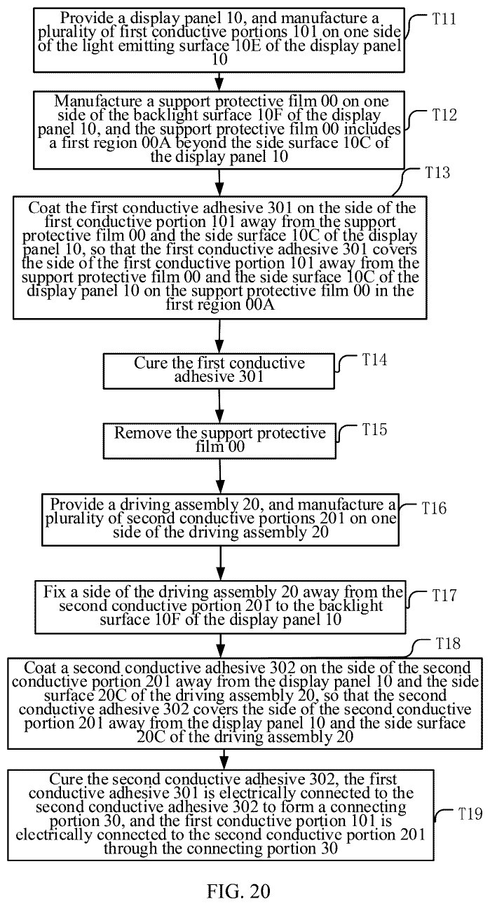

FIG. 20 is a flowchart of a method for manufacturing a display device according to some embodiments of the present disclosure. In some embodiments, referring to FIG. 1 to FIG. 3, FIG. 6 to FIG. 7, and FIG. 20, the method for manufacturing the display device according to the embodiments of the present disclosure may be used to manufacture the display device 000 provided in the embodiments of FIG. 1 to FIG. 3 and FIG. 6 to FIG. 7. The method includes as follows.

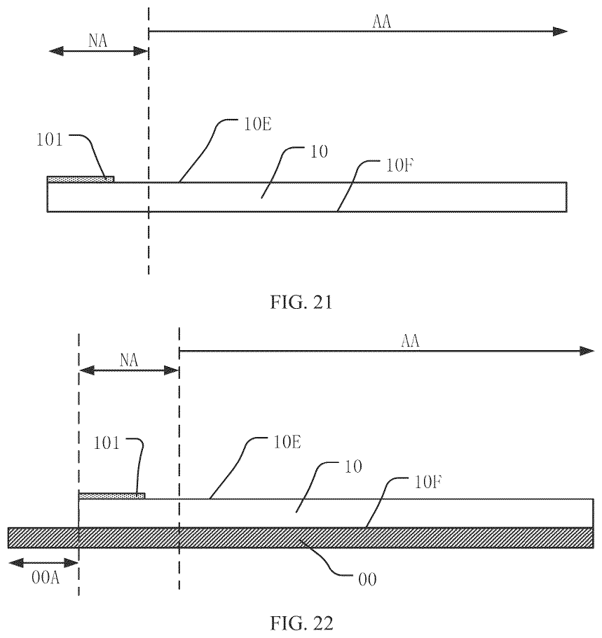

T11: a display panel 10 is provided, and a plurality of first conductive portions 101 are manufactured on a side of the light-emitting surface 10E of the display panel 10. In some embodiments, the display panel 10 may be either one of the flexible display panel or the rigid display panel. The display panel 10 may also be an OLED display panel. The first conductive portions 101 may be manufactured within the range of the non-display region NA of the display panel 10. The display region AA of the display panel 10 may be configured to arrange sub-pixels for displaying images. As shown in FIG. 21, FIG. 21 is a structural schematic diagram of a display panel provided in the method of FIG. 20. In some embodiments, the display panel 10 includes a light-emitting surface 10E and a backlight surface 10F opposite to each other. The light-emitting surface 10E of the display panel 10 may be understood as a surface on which sub-pixels in the display region AA of the display panel 10 emit light, or may also be understood as a surface on which a user views a displayed image. The backlight surface 10F of the display panel 10 may be understood as another side surface of the display panel 10 opposite to the light-emitting surface 10E. When manufacturing the first conductive portions 101 on a side of the light-emitting surface 10E of the display panel 10, a metallic titanium layer inherently included in the display panel 10 may be used and formed by a mask evaporation process. In some embodiments, in the method according to the embodiments of the present disclosure, manufacturing the first conductive portions 101 on a side of the light-emitting surface 10E of the display panel 10 may include: a bonding region on a side of the non-display region NA of the light-emitting surface 10E of the display panel 10 is provided, a metallic titanium layer is manufactured in the bonding region, and the metallic titanium layer is exposed and developed through a mask, so as to form the first conductive portions 101.

It should be noted that the specific structure of the display panel 10 is not described in detail in the embodiments of the present disclosure. For example, the display panel 10 may further include structures such as a polarizer and a cover plate, which are not shown in FIG. 21. The understanding may be made with reference to the structures of organic light-emitting display panels in the related art.

T12: a support protective film 00 is manufactured on a side of the backlight surface 10F of the display panel 10, and the support protective film 00 includes a first region 00A beyond the side surface 10C of the display panel 10. As shown in FIG. 22, FIG. 22 is a structural schematic diagram after manufacturing a support protective film on a side of a backlight surface of the display panel in the method of FIG. 20. By manufacturing the support protective film 00 on a side of the backlight surface 10F of the display panel 10, within the first region 00A of the support protective film 00 extending beyond the side surface 10C of the display panel 10, it is convenient for subsequently coating the first conductive adhesive 301 on the side surface of the display panel 10 and on the surface of the first conductive portions 101, to prevent unnecessary slipping that may occur during subsequent coating of the first conductive adhesive 301, thereby achieving the coating reliability and manufacturing efficiency of the first conductive adhesive 301. In addition, when the display panel 10 is a flexible display panel, the supporting function can also be provided, which facilitates subsequent processes.

T13: the first conductive adhesive 301 is coated on the side of the first conductive portion 101 away from the support protective film 00 and the side surface 10C of the display panel 10, so that the first conductive adhesive 301 covers the side of the first conductive portion 101 away from the support protective film 00 and the side surface 10C of the display panel 10 on the support protective film 00 in the first region 00A.

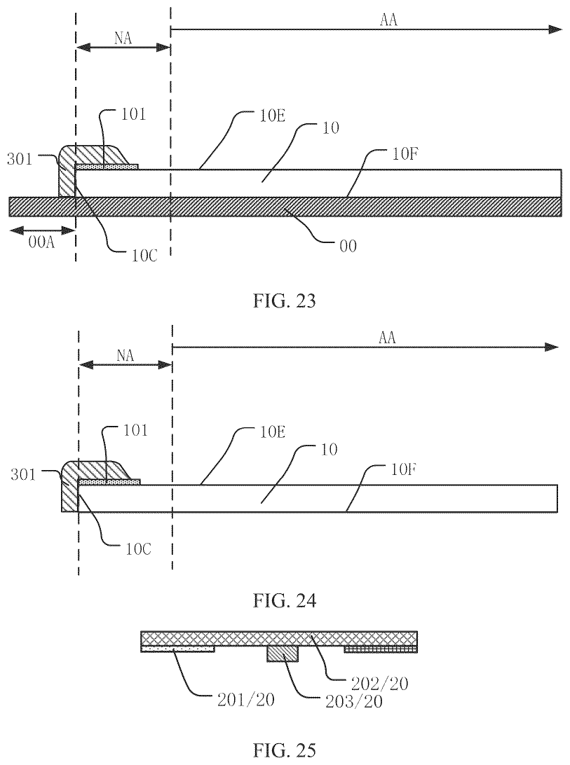

T14: the first conductive adhesive 301 is cured. As shown in FIG. 23, FIG. 23 is a structural schematic diagram after manufacturing a first conductive adhesive in the method of FIG. 20. In some embodiments, when curing the first conductive adhesive 301, thermal curing or laser curing may be adopted. The material of the first conductive adhesive 301 may be a conductive adhesive material containing metallic silver and metallic copper. The conductive adhesive material doped with metallic silver and metallic copper is used as the first conductive adhesive 301 and coated on the side of the first conductive portion 101 away from the support protective film 00 and the side surface 10C of the display panel 10, which can achieve the conductivity of the first conductive adhesive 301, and achieve the adhesion when the first conductive adhesive 301 is coated on the side of the first conductive portion 101 away from the support protective film 00 and the side surface 10C of the display panel 10, thereby facilitating improving the reliability of electrical connection.

T15: the support protective film 00 is removed. In some embodiments, the support protective film 00 on a side of the backlight surface 10F of the display panel 10 may be removed by peeling. As shown in FIG. 24, FIG. 24 is a structural schematic diagram after removing the support protective film in the method of FIG. 20.

T16: a driving assembly 20 is provided, and a plurality of second conductive portions 201 are manufactured on a side of the driving assembly 20. As shown in FIG. 25, FIG. 25 is a structural schematic diagram of a driving assembly provided in the method of FIG. 20. FIG. 25 only illustrates an example in which the driving assembly 20 is designed as a chip-on-film structure (the chip-on-film itself includes the first flexible circuit board 202 and the driving chip 203). In specific implementation, the driving assembly 20 may also be other structures, which may be understood with reference to the description of the above embodiments for details. For example, the driving assembly 20 may adopt a COF technology or a COG technology, and details are not elaborated herein. The driving assembly 20 may be a structure for providing a driving signal, such as a driving chip and/or a flexible circuit board, and is configured to be electrically connected to the display panel 10 to provide a driving signal for the display panel 10, so as to achieve the display function of the display panel, and the like. In some embodiments, the material of the second conductive portions 201 manufactured on a side of the driving assembly 20 may include metallic copper. For example, manufacturing the second conductive portions 201 on a side of the driving assembly 20 may include: a metallic copper layer is manufactured on a side of the driving assembly, the second conductive portions 201 are formed by an etching process, and the second conductive portions 201 is manufactured by the etching process using a metallic copper layer, so that the second conductive portion 201 may be manufactured using a metallic copper layer of the flexible circuit board of the driving assembly 20, thereby saving the manufacturing cost and reducing the process difficulty.

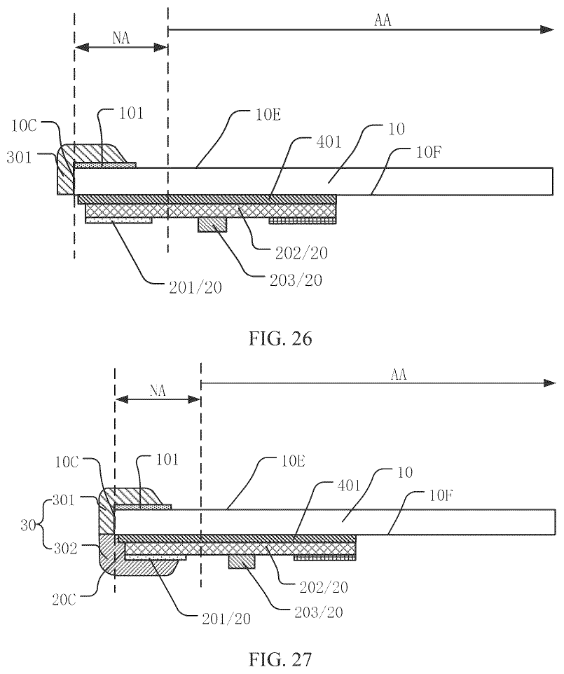

T17: a side of the driving assembly 20 away from the second conductive portion 201 is fixed to the backlight surface 10F of the display panel 10. As shown in FIG. 26, FIG. 26 is a structural schematic diagram after fixing the driving assembly and the display panel in the method of FIG. 20. In some embodiments, a first pressure sensitive adhesive layer 401 is coated on a side of the backlight surface 10F of the display panel 10, and a side of the driving assembly 20 facing away from the second conductive portion 201 is fixed with the backlight surface 10F of the display panel 10 through the first pressure sensitive adhesive layer 401. In some embodiments, when the driving assembly 20 is entirely arranged on a side of the backlight surface 10F of the display panel 10, the first pressure sensitive adhesive layer 401 (Pressure Sensitive Adhesives, PSA) may be arranged on a side of the backlight surface 10F of the display panel 10. The adhesive fixing between the backlight surface 10F of the display panel 10 and the driving assembly 20 can be realized by applying slight pressure, without heating, solvents or other complex curing processes, which simplifies the process steps and improves the process efficiency.

T18: a second conductive adhesive 302 is coated on the side of the second conductive portion 201 away from the display panel 10 and the side surface 20C of the driving assembly 20, so that the second conductive adhesive 302 covers the side of the second conductive portion 201 away from the display panel 10 and the side surface 20C of the driving assembly 20.

T19: the second conductive adhesive 302 is cured. The first conductive adhesive 301 is electrically connected to the second conductive adhesive 302 to form a connecting portion 30, and the first conductive portion 101 is electrically connected to the second conductive portion 201 through the connecting portion 30. As shown in FIG. 27, FIG. 27 is a structural schematic diagram after manufacturing a second conductive adhesive in the method of FIG. 20. In some embodiments, when curing the second conductive adhesive 302, a manner such as thermal curing or laser curing may be adopted. The material of the second conductive adhesive 302 may be the same as the material of the first conductive adhesive 301 (different patterns filling in the figure are merely for distinguishing illustration and does not indicate that the materials are different), and may be a conductive adhesive material containing metallic silver and metallic copper. The conductive adhesive material doped with metallic silver and metallic copper is used as the second conductive adhesive 302 and coating it on the side of the second conductive portion 201 away from the display panel 10 and the side surface 20C of the driving assembly 20, which can achieve the conductivity of the second conductive adhesive 302, and achieve the adhesion when the second conductive adhesive 302 is coated on the side of the second conductive portion 201 away from the display panel 10 and the side surface 20C of the driving assembly 20, thereby facilitating improving the reliability of electrical connection.

According to the method of the embodiments of the present disclosure, after the driving assembly 20 is completely arranged on a side of the backlight surface 10F of the display panel 10, it is equivalent to canceling the bending design of the driving assembly 20, and the electrical signal transmission between the display panel 10 and the driving assembly 20 can be realized, which can effectively prevent the problems that cracks caused by bending lead to breakage of internal traces of the driving assembly 20 and unreliable bending strength, thereby affecting the display quality and the process yield. In addition, after canceling the bending design of the driving assembly, the bezel space of the display device originally occupied by the bent portion of the driving assembly 20 will also disappear, leaving only the width occupied by the first conductive adhesive 301 and the second conductive adhesive 302 on the side surface 10C of the display panel 10 and the side surface 20C of the driving assembly 20. In the method according to the embodiments of the present disclosure, when the first conductive portion 101 is electrically connected to the second conductive portion 201, the first conductive adhesive 301 is coated to cover the surface of the side of the first conductive portion 101 away from the backlight surface 10F of the display panel 10 and the side surface 10C of the display panel 10. After curing the first conductive adhesive 301, the driving assembly 20 is entirely arranged on a side of the backlight surface 10F of the display panel 10 and is fixed to the display panel 10, and then the second conductive adhesive 302 is coated to cover the surface of the side of the second conductive portion 201 away from the display panel 10, the side surface 20C of the driving assembly 20 and the side surface of the first pressure sensitive adhesive layer 401. The cured second conductive adhesive 302 and the first conductive adhesive 301 jointly form the connecting portion 30. The connecting portions 30 are arranged in one-to-one correspondence with the first conductive portions 101 and the second conductive portions 201, that is, one connecting portion 30 is correspondingly electrically connected to one first conductive portion 101 and one second conductive portion 201, so as to realize electrical signal transmission between the first conductive portion 101 on a side of the light-emitting surface 10E of the display panel 10 and the second conductive portion 201 on the side of the driving assembly 20 away from the display panel 10. The second conductive adhesive 302 and the first conductive adhesive 301 jointly form the connecting portion 30, and the connecting portion 30 may be coated to cover the surface of the side of the first conductive portion 101 away from the second conductive portion 201, the surface of the side of the second conductive portion 201 away from the first conductive portion 101, the side surface 10C of the display panel 10, and the side surface 20C of the driving assembly 20. Therefore, the width occupied by the connecting portion 30 on the side surface 10C of the display panel 10 and the side surface 20C of the driving assembly 20 is greatly reduced as compared with the bezel width occupied when the driving assembly is bent to a side of the backlight surface of the display panel in the related art, thereby facilitating further realizing the narrow-bezel or even bezel-less effect, effectively avoiding the problems such cracks or open circuits, achieving the reliability of the electrical connection between the driving assembly 20 and the display panel 10, and improving the display quality and the process yield.

It should be noted that the method for manufacturing the display device according to the embodiments of the present disclosure includes but is not limited to the above steps, and may also include other method steps such as manufacturing a polarizer and a cover plate, which will not be elaborated herein in the embodiments. The method according to the embodiments of the present disclosure mainly illustrates the formation of the connecting portion 30 and a manufacturing process in which the driving assembly 20 is entirely arranged on a side of the backlight surface 10F of the display panel 10. Other manufacturing processes may be set with reference to the process for manufacturing the display device in the related art.

In the method according to the embodiments of the present disclosure, the first conductive adhesive 301 is coated on the side of the first conductive portion 101 away from the support protective film 00 and the side surface 10C of the display panel 10, so that the first conductive adhesive 301 covers the side of the first conductive portion 101 away from the support protective film 00 and the side surface 10C of the display panel 10 on the support protective film 00 in the first region 00A. The second conductive adhesive 302 is coated on the side of the second conductive portion 201 away from the display panel 10 and the side surface 20C of the driving assembly 20, so that the second conductive adhesive 302 covers the side of the second conductive portion 201 away from the display panel 10 and the side surface 20C of the driving assembly 20. The electrohydrodynamic inkjet (EHD inkjet) printing technology may be adopted to coat the first conductive adhesive 301 and the second conductive adhesive 302. The electrohydrodynamic inkjet printing technology is a high-precision printing technology that controls droplet ejection using a high-voltage electric field, and the liquid may be driven to form a fine jet or droplet using high-voltage electric field force, so as to realizing high-resolution and high-precision micro-nano scale patterned deposition. Compared with traditional inkjet printing (such as thermal bubble type or piezoelectric type), the EHD inkjet printing technology has characteristics such as low energy consumption, high resolution, good material compatibility, and strong controllability, thereby realizing that the first conductive adhesive 301 is in one-to-one correspondence with the first conductive portions 101 and the coated first conductive adhesive 301 does not encroach on spaces between adjacent first conductive portions 101, and the second conductive adhesive 302 is in one-to-one correspondence with the second conductive portions 201 and the coated second conductive adhesive 302 does not encroach on spaces between adjacent second conductive portions 201, thereby effectively realizing the high-precision coating effect.

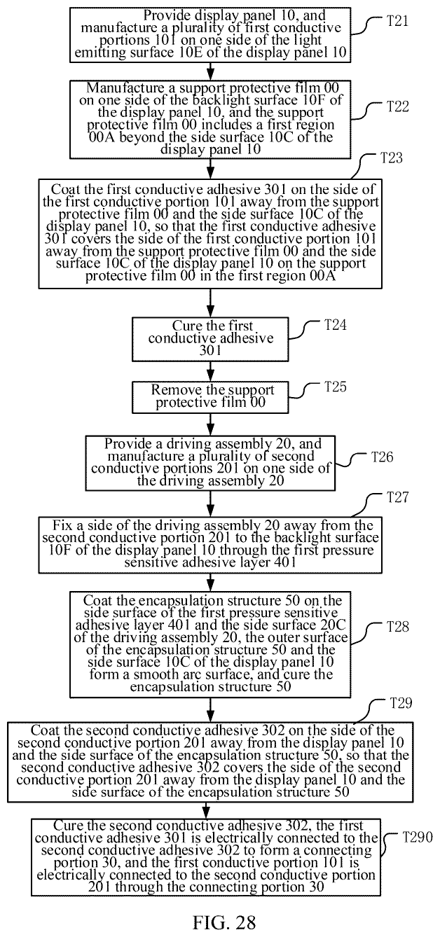

FIG. 28 is a flowchart of a method for manufacturing a display device according to some embodiments of the present disclosure. In some embodiments, referring to FIG. 1, FIG. 6, FIG. 15, FIG. 21 to FIG. 26 and FIG. 28, the method for manufacturing the display device according to the embodiments of the present disclosure may be used to manufacture the display device 000 provided in the embodiments of FIG. 1, FIG. 6 and FIG. 15. The method includes as follows.

T21: a display panel 10 is provided, and a plurality of first conductive portions 101 are manufactured on a side of the light-emitting surface 10E of the display panel 10, as shown in FIG. 21.

T22: a support protective film 00 is manufactured on a side of the backlight surface 10F of the display panel 10, and the support protective film 00 includes a first region 00A beyond the side surface 10C of the display panel 10, as shown in FIG. 22.

T23: the first conductive adhesive 301 is coated on the side of the first conductive portion 101 away from the support protective film 00 and the side surface 10C of the display panel 10, so that the first conductive adhesive 301 covers the side of the first conductive portion 101 away from the support protective film 00 and the side surface 10C of the display panel 10 on the support protective film 00 in the first region 00A.

T24: the first conductive adhesive 301 is cured, as shown in FIG. 23.

T25: the support protective film 00 is removed, as shown in FIG. 24.

T26: a driving assembly 20 is provided, and a plurality of second conductive portions 201 are manufactured on a side of the driving assembly 20, as shown in FIG. 25.

T27: a side of the driving assembly 20 away from the second conductive portion 201 is fixed to the backlight surface 10F of the display panel 10 through the first pressure sensitive adhesive layer 401, as shown in FIG. 26.

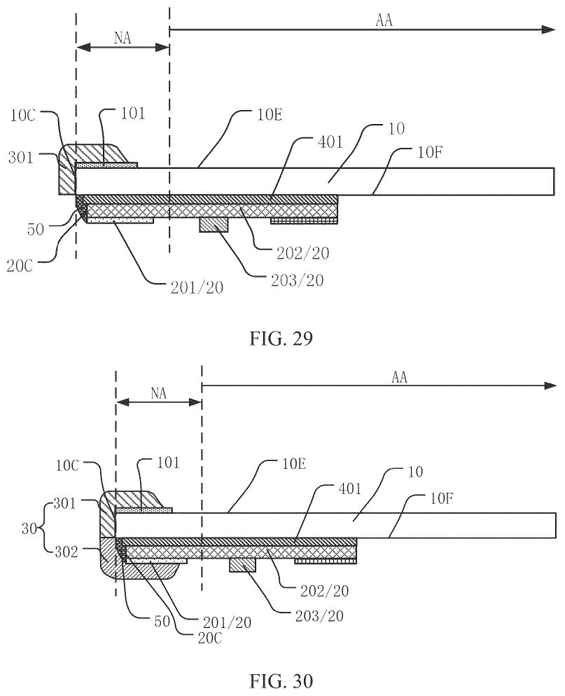

T28: the encapsulation structure 50 is coated on the side surface of the first pressure sensitive adhesive layer 401 and the side surface 20C of the driving assembly 20, and the outer surface of the encapsulation structure 50 and the side surface 10C of the display panel 10 form a smooth arc surface. In some embodiments, the method further includes: the encapsulation structure 50 is cured. As shown in FIG. 29, FIG. 29 is a structural schematic diagram after manufacturing an encapsulation structure in the method of FIG. 28.

T29: the second conductive adhesive 302 is coated on the side of the second conductive portion 201 away from the display panel 10 and the side surface of the encapsulation structure 50, so that the second conductive adhesive 302 covers the side of the second conductive portion 201 away from the display panel 10 and the side surface of the encapsulation structure 50.

T290: the second conductive adhesive 302 is cured. The first conductive adhesive 301 is electrically connected to the second conductive adhesive 302 to form a connecting portion 30, and the first conductive portion 101 is electrically connected to the second conductive portion 201 through the connecting portion 30. As shown in FIG. 30, FIG. 30 is a structural schematic diagram after manufacturing a second conductive adhesive in the method of FIG. 28.

In the method according to the embodiments of the present disclosure, before coating the second conductive adhesive 302 on the side of the second conductive portion 201 away from the display panel 10 and the side surface 20C of the driving assembly 20, the method further includes: the encapsulation structure 50 is coated on the side surface of the first pressure sensitive adhesive layer 401 and the side surface 20C of the driving assembly 20, the outer surface of the encapsulation structure 50 and the side surface 10C of the display panel 10 form a smooth arc surface, and the encapsulation structure 50 is cured. The encapsulation structure 50 can achieve that a uniform thickness can be formed when coating the second conductive adhesive 302. In addition, the outer surface of the encapsulation structure 50 and the side surface 10C of the display panel 10 form a smooth arc surface, which can further enable the second conductive adhesive 302, when being coated, to be tightly coated and cured on the smooth arc surface of the encapsulation structure 50, thereby avoiding the formation of cavities between the second conductive adhesive 302 and the encapsulation structure 50, and achieving the process reliability of the product. In addition, the exposed outer surface of the connecting portion 30 formed by the contact electrical connection between the first conductive adhesive 301 and the second conductive adhesive 302 can finally be formed smoothly, and the corners of the display device can have fewer sharp structures, which achieves the product yield.

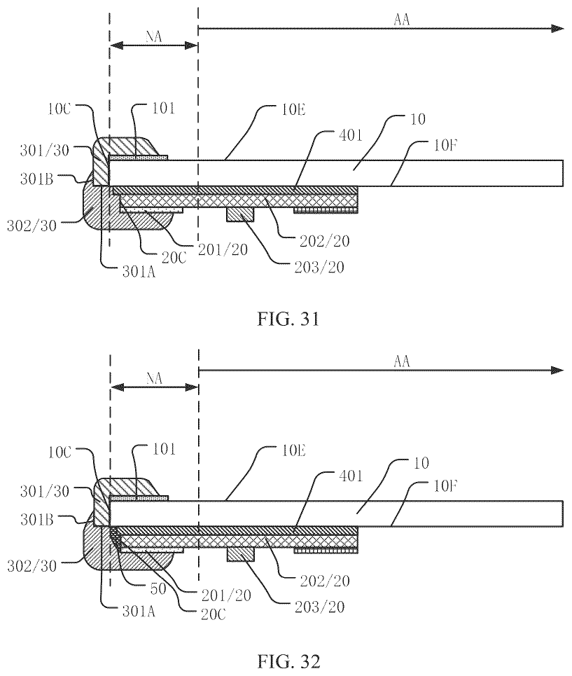

In some embodiments, referring to FIG. 20, FIG. 28, FIG. 31, and FIG. 32, FIG. 31 is a structural schematic diagram after manufacturing the second conductive adhesive in the method of FIG. 20, and FIG. 32 is a structural schematic diagram after manufacturing the second conductive adhesive in the method of FIG. 28. In the method provided in FIG. 20 and FIG. 28 of the embodiments, when the second conductive adhesive 302 is coated on the side of the second conductive portion 201 away from the display panel 10 and the side surface 20C of the driving assembly 20, so that the second conductive adhesive 302 covers the side of the second conductive portion 201 away from the display panel 10 and the side surface 20C of the driving assembly 20, or the second conductive adhesive 302 is coated on the side of the second conductive portion 201 away from the display panel 10 and the side surface of the encapsulation structure 50, so that the second conductive adhesive 302 covers the side of the second conductive portion 201 away from the display panel 10 and the side surface of the encapsulation structure 50, the coated second conductive adhesive 302 may cover the first side 301A of the first conductive adhesive 301 and at least cover a part of the second side 301B of the first conductive adhesive 301. The first side 301A is flush with the backlight surface 10F of the display panel 10, and the second side 301B is arranged opposite to the side surface 10C of the display panel 10.

Some embodiments illustrates that, in order to achieve contact reliability with the first conductive adhesive 301 after the second conductive adhesive 302 is coated, when the second conductive adhesive 302 is coated on the side of the second conductive portion 201 away from the display panel 10 and the side surface 20C of the driving assembly 20, or the second conductive adhesive 302 is coated on the side of the second conductive portion 201 away from the display panel 10 and the side surface of the encapsulation structure 50, the second conductive adhesive 302 further covers a part of the first conductive adhesive 301. That is, the second conductive adhesive 302 needs to at least cover the first side 301A of the first conductive adhesive 301 and at least covers a part of the second side 301B of the first conductive adhesive 301 (for example, the first side 301A and the second side 301B of the first conductive adhesive 301 shown in FIG. 31 and FIG. 32), thereby increasing the contact area between the second conductive adhesive 302 and the first conductive adhesive 301, achieving the overall electrical connection reliability of the formed connecting portion 30, facilitating reducing the probability that cracks occur at the contact interface between the second conductive adhesive 302 and the first conductive adhesive 301 in the connecting portion 30, and thus improving the product yield.

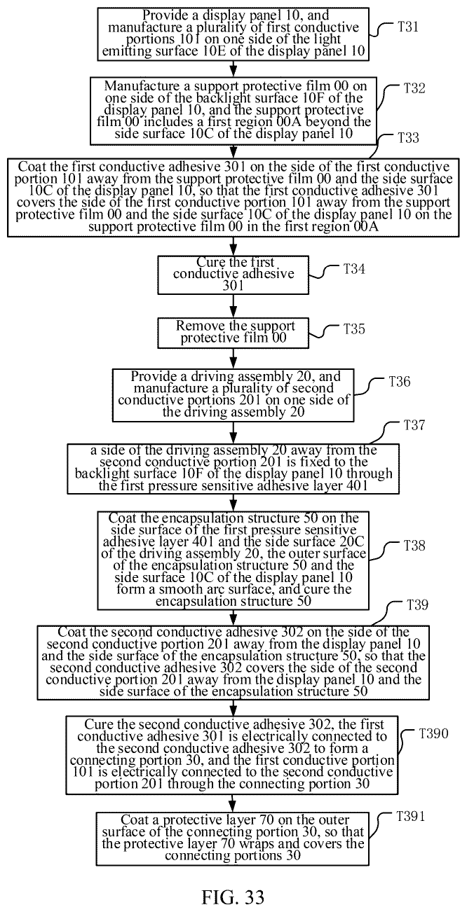

FIG. 33 is a flowchart of a method for manufacturing a display device according to some embodiments of the present disclosure. In some embodiments, referring to FIG. 17 to FIG. 19, FIG. 21 to FIG. 26, FIG. 29 to FIG. 32 and FIG. 33, the method for manufacturing the display device according to the embodiments of the present disclosure may be used to manufacture the display device 000 provided in the embodiments of FIG. 17 to FIG. 19. The method includes as follows.

T31: a display panel 10 is provided, and a plurality of first conductive portions 101 are manufactured on a side of the light-emitting surface 10E of the display panel 10, as shown in FIG. 21.

T32: a support protective film 00 is manufactured on a side of the backlight surface 10F of the display panel 10, and the support protective film 00 includes a first region 00A beyond the side surface 10C of the display panel 10, as shown in FIG. 22.

T33: the first conductive adhesive 301 is coated on the side of the first conductive portion 101 away from the support protective film 00 and the side surface 10C of the display panel 10, so that the first conductive adhesive 301 covers the side of the first conductive portion 101 away from the support protective film 00 and the side surface 10C of the display panel 10 on the support protective film 00 in the first region 00A.

T34: the first conductive adhesive 301 is cured, as shown in FIG. 23.

T35: the support protective film 00 is removed, as shown in FIG. 24.

T36: a driving assembly 20 is provided, and a plurality of second conductive portions 201 are manufactured on a side of the driving assembly 20, as shown in FIG. 25.

T37: a side of the driving assembly 20 away from the second conductive portion 201 is fixed to the backlight surface 10F of the display panel 10 through the first pressure sensitive adhesive layer 401, as shown in FIG. 26.

T38: the encapsulation structure 50 is coated on the side surface of the first pressure sensitive adhesive layer 401 and the side surface 20C of the driving assembly 20, and the outer surface of the encapsulation structure 50 and the side surface 10C of the display panel 10 form a smooth arc surface. In some embodiments, the method further includes: the encapsulation structure 50 is cured, as shown in FIG. 29.

T39: the second conductive adhesive 302 is coated on the side of the second conductive portion 201 away from the display panel 10 and the side surface of the encapsulation structure 50, so that the second conductive adhesive 302 covers the side of the second conductive portion 201 away from the display panel 10 and the side surface of the encapsulation structure 50.

T390: the second conductive adhesive 302 is cured. The first conductive adhesive 301 is electrically connected to the second conductive adhesive 302 to form a connecting portion 30, and the first conductive portion 101 is electrically connected to the second conductive portion 201 through the connecting portion 30, as shown in FIG. 30.

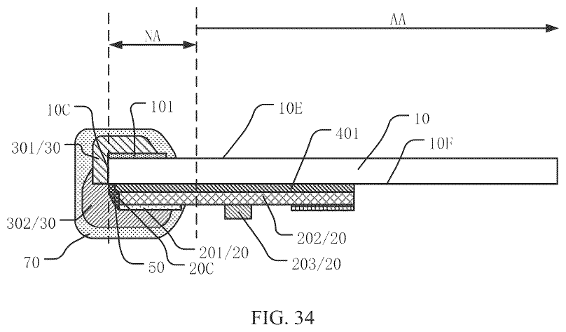

T391: a protective layer 70 is coated on the outer surface of the connecting portion 30, so that the protective layer 70 wraps and covers the connecting portions 30. In some embodiments, the protective layer 70 covers at least part of the surface of the display panel 10 on a side of the light-emitting surface 10E of the display panel 10. The protective layer 70 covers at least part of the surface of the driving assembly 20 on a side of the driving assembly 20 away from the display panel 10. As shown in FIG. 34, FIG. 34 is a structural schematic diagram after manufacturing a protective layer in the method of FIG. 33.

In the method according to the embodiments of the present disclosure, after the connecting portion 30 is formed, a coating process of the protective layer 70 is further performed, that is, the protective layer 70 is coated on the outer surface of the connecting portion 30, so that the protective layer 70 wraps and covers the connecting portions 30. For example, the protective layer 70 covers at least part of the surface of the display panel 10 on a side of the light-emitting surface 10E of the display panel 10, and the protective layer 70 covers at least part of the surface of the driving assembly 20 on a side of the driving assembly 20 away from the display panel 10, thereby enabling the protective layer 70 to wrap and cover the connecting portions 30. The protective layer 70 may be subjected to ordinary UV curing using an acrylic material, or UV curing and moisture curing using an acrylic material in combination, so that the protective layer 70 covering the connecting portions 30 may have effects of preventing corrosion of the connecting portions 30 caused by moisture permeation and protecting the connecting portions 30 from impact, thereby improving the reliability of the display device.

It should be noted that, in this context, relational terms such as “first” and “second” are merely used to distinguish one entity or operation from another entity or operation, and do not necessarily require or imply any actual relationship or sequence between these entities or operations. Further, terms such as “include”, “comprise” or any other variations thereof are intended to cover a non-exclusive inclusion, thus a process, method, item or device including a series of elements includes not only those elements, but also other elements not explicitly listed, or elements inherent in such the process, method, item or device. Without more limitations, an element defined by the statement “including a . . . ” does not exclude the existence of other identical elements in a process, a method, an article, or a device that include the element.

The above description is only some embodiments of the present disclosure, so that those skilled in the art can understand or implement the present disclosure. Various modifications to these embodiments will be apparent to those skilled in the art, and the general principles defined herein may be implemented in other embodiments without departing from the spirit or scope of the present disclosure. Accordingly, the present disclosure will not be limited to the embodiments described herein but should be interpreted to have the broadest scope in conformity with the principles and innovations disclosed in the present disclosure.

What is claimed is:

1. A display device, comprising a display panel, a plurality of first conductive portions, a plurality of second conductive portions, a plurality of connecting portions, and a driving assembly,
wherein the display panel comprises a light-emitting surface and a backlight surface opposite to each other, and the driving assembly is located on a side of the backlight surface;
wherein the plurality of first conductive portions is provided on a side of the light-emitting surface of the display panel, and the plurality of second conductive portions is provided on a side of the driving assembly away from the display panel;
wherein one of the plurality of connecting portions at least covers a surface of a side of one of the plurality of first conductive portions away from one of the plurality of second conductive portions, a surface of a side of one of the plurality of second conductive portions away from one of the plurality of first conductive portions, a side surface of the display panel, and a side surface of the driving assembly; and
one of the plurality of first conductive portions is electrically connected to one of the plurality of second conductive portions through one of the plurality of connecting portions.

2. The display device according to claim 1, wherein an area of the connecting portion covering the first conductive portion is S1, and an orthographic projection area of the first conductive portion on a plane of the display panel is S2, where 0.6S2≤S1≤0.8 S2.

3. The display device according to claim 1, wherein along an arrangement direction of the plurality of first conductive portions, a distance between two adjacent first conductive portions is D0, where 30 μm≤D0≤100 μm.

4. The display device according to claim 1, wherein
the side surface of the display panel comprises a first edge facing the plurality of connecting portions, and the side surface of the driving assembly comprises a second edge facing the plurality of connecting portions; and
along a direction parallel to a plane of the display panel, a distance from the second edge to the first edge is D1, where D1>0.

5. The display device according to claim 1, wherein a first pressure sensitive adhesive layer is provided between the display panel and the driving assembly, and the side of the backlight surface of the display panel is fixed to the driving assembly through the first pressure sensitive adhesive layer.

6. The display device according to claim 5, wherein
the side surface of the display panel comprises a first edge facing the plurality of connecting portions, and a side surface of the first pressure sensitive adhesive layer comprises a third edge facing the plurality of connecting portions; and
along a direction parallel to a plane of the display panel, a distance from the third edge to the first edge is D2, where D2>0.

7. The display device according to claim 5, wherein
the side surface of the display panel comprises a first edge facing the plurality of connecting portions, the side surface of the driving assembly comprises a second edge facing the plurality of connecting portions, and a side surface of the first pressure sensitive adhesive layer comprises a third edge facing the plurality of connecting portions; and
along a direction parallel to a plane of the display panel, a distance from the second edge to the first edge is D11, and a distance from the third edge to the first edge is D22, where D11≥D22.

8. The display device according to claim 7, wherein an encapsulation structure is filled between the side surface of the first pressure sensitive adhesive layer and one of the plurality of connecting portions and between the side surface of the driving assembly and one of the plurality of connecting portions; and
a surface of the encapsulation structure facing the plurality of connecting portions is a smooth arc surface.

9. The display device according to claim 5, wherein an ultra-clean foam composite film is provided on the side of the backlight surface of the display panel, the ultra-clean foam composite film is independent of the first pressure sensitive adhesive layer, and the ultra-clean foam composite film is located on a side of the first pressure sensitive adhesive layer away from an edge of the display panel; and
a side of the ultra-clean foam composite film away from the light-emitting surface of the display panel is fixed to the driving assembly through a second pressure sensitive adhesive layer.

10. The display device according to claim 1, wherein
a material for manufacturing the first conductive portion comprises metallic titanium, and a material for manufacturing the second conductive portion comprises metallic copper.

11. The display device according to claim 10, wherein a material of the plurality of connecting portions comprises a conductive adhesive material containing metallic silver and metallic copper.

12. The display device according to claim 1, further comprising a protective layer covering the plurality of connecting portions.

13. The display device according to claim 12, wherein
on the side of the light-emitting surface of the display panel, the protective layer covers at least part of a surface of the display panel; and
on the side of the driving assembly away from the display panel, the protective layer covers at least part of a surface of the driving assembly.

14. The display device according to claim 1, wherein
the driving assembly comprises a flexible circuit board; and
a driving chip is provided on the side of the light-emitting surface of the display panel, and the driving chip is electrically connected to the flexible circuit board through the plurality of first conductive portions, the plurality of connecting portions, and the plurality of second conductive portions.

15. The display device according to claim 1, wherein
the driving assembly comprises a chip-on-film; and
the chip-on-film comprises a first flexible circuit board and a driving chip, and a side of the first flexible circuit board away from the display panel comprises the second conductive portion and the driving chip.

16. A method for manufacturing a display device according to claim 1, comprising:
providing the display panel, and manufacturing the first conductive portions on the side of the light-emitting surface of the display panel;
manufacturing the support protective film on the side of the backlight surface of the display panel, wherein the support protective film comprises the first region beyond the side surface of the display panel;
coating the first conductive adhesive on a side of the first conductive portion away from the support protective film, so that on the support protective film in the first region, the first conductive adhesive covers the side of the first conductive portion away from the support protective film and the side surface of the display panel;
curing the first conductive adhesive;
removing the support protective film;
providing the driving assembly, and manufacturing the second conductive portions on a side of the driving assembly;
fixing a side of the driving assembly away from the second conductive portion to the backlight surface of the display panel;
coating the second conductive adhesive on a side of the second conductive portion away from the display panel and the side surface of the driving assembly, so that the second conductive adhesive covers the side of the second conductive portion away from the display panel and the side surface of the driving assembly; and
curing the second conductive adhesive,
wherein the first conductive adhesive is electrically connected to the second conductive adhesive to form the plurality of connecting portions, and one of the plurality of first conductive portion is electrically connected to one of the plurality of second conductive portion through the plurality of connecting portions.

17. The method according to claim 16, wherein said fixing a side of the driving assembly away from the second conductive portion to the backlight surface of the display panel comprises:
coating a first pressure sensitive adhesive layer on the side of the backlight surface of the display panel, and fixing the side of the driving assembly away from the second conductive portion to the backlight surface of the display panel through the first pressure sensitive adhesive layer.

18. The method according to claim 17, wherein before said coating the second conductive adhesive on a side of the second conductive portion away from the display panel and the side surface of the driving assembly, the method further comprises:
coating an encapsulation structure on a side surface of the first pressure sensitive adhesive layer and the side surface of the driving assembly, wherein an outer surface of the encapsulation structure and the side surface of the display panel form a smooth arc surface.

19. The method according to claim 16, wherein said manufacturing the first conductive portions on the side of the light-emitting surface of the display panel comprises:
the side of the light-emitting surface of the display panel comprises a bonding region, a metallic titanium layer is formed in the bonding region, and the metallic titanium layer is exposed and developed through a mask, to form the first conductive portions.

20. The method according to claim 16, wherein said manufacturing the second conductive portions on a side of the driving assembly comprises:
forming a metallic copper layer on a side of the driving assembly, and forming the second conductive portions through an etching process.
